(19) United States
(12) Patent Application Publication
(10) Pub. No.: US 2026/0196999 A1
(43) Pub. Date: Jul. 9, 2026

(54) SIGNAL OUTPUT CIRCUIT, SWITCHING CONTROL CIRCUIT, AND SEMICONDUCTOR DEVICE

(71) Applicant: FUJI ELECTRIC CO., LTD., Kawasaki-shi (JP)

(72) Inventor: Masashi AKAHANE, Matsumoto-city (JP)

(73) Assignee: FUJI ELECTRIC CO., LTD., Kawasaki-shi (JP)

(21) Appl. No.: 19/402,723

(22) Filed: Nov. 26, 2025

(30) Foreign Application Priority Data
Jan. 9, 2025 (JP) 2025-003506

(51) Int. Cl. H03K 17/16; H03K 17/28; H03K 19/003

(52) U.S. Cl. CPC H03K 17/168; H03K 17/28; H03K 19/00353

(57) ABSTRACT

A signal output circuit outputting an output signal corresponding to an input signal, each of the input and output signals being at a logic level that is a first logic level or a second logic level. The signal output circuit includes: a first capacitor; a charge-discharge circuit configured to: charge the first capacitor when the input signal is at the second logic level and discharge the first capacitor when the output signal reaches the second logic level, and charge the first capacitor when the input signal is at the first logic level and discharges the first capacitor when the output signal reaches the first logic level, while the output signal is at the first logic level and the second logic level, respectively; and an inverting circuit inverting the logic level of the output signal, in response to a charge voltage of the first capacitor exceeding a reference voltage.

### CROSS-REFERENCE TO RELATED APPLICATIONS

The present application claims priority pursuant to 35 U.S.C. §119 from Japanese patent application number 2025-003506 filed on January 9, 2025, the entire disclosure of which is hereby incorporated by reference herein.

### BACKGROUND

### Technical Field

The present disclosure relates to a signal output circuit, a switching control circuit, and a semiconductor device.

### Description of the Related Art

There have been signal output circuits that output an output signal corresponding to an input signal (for example, Japanese Patent No. 7024374, Japanese Patent Application Publication No. 2008-125342, Japanese Patent No. 7523552, and Japanese Patent Application Publication No. 2019-080436).

These signal output circuits as described above generally output the output signal corresponding to the input signal, and thus when noise is superimposed on the input signal, the output signal is changed accordingly. In order to obtain an output signal based on an input signal, removal of noise from the input signal may be performed in a signal output circuit. However, in general, the size of a circuit that removes noise from the input signal is large.

### SUMMARY

A first aspect of the present disclosure is a signal output circuit configured to output an output signal corresponding to an input signal thereof, each of the input signal and the output signal being at a logic level that is either a first logic level or a second logic level, the signal output circuit comprising: a first capacitor; a charge-discharge circuit configured to, in a case where the output signal is at the first logic level, charge the first capacitor when the input signal is at the second logic level, and discharge the first capacitor when the output signal reaches the second logic level, and in a case where the output signal is at the second logic level, charge the first capacitor when the input signal is at the first logic level, and discharges the first capacitor when the output signal reaches the first logic level; and an inverting circuit configured to invert the logic level of the output signal, in response to a charge voltage of the first capacitor exceeding a reference voltage.

A second aspect of the present disclosure is a switching control circuit, comprising: an input signal output circuit configured to output an input signal at a logic level that is based on a magnitude relationship between a temperature of a switching device and a predetermined temperature; a signal output circuit configured to output an output signal corresponding to the input signal; and a driver circuit configured to switch the switching device, in response to a drive signal for driving the switching device and the output signal.

A third aspect of the present disclosure is a semiconductor device, comprising: a switching device; a temperature detection element configured to detect a temperature of the switching device; an input signal output circuit configured to output an input signal; a signal output circuit configured to output an output signal corresponding to the input signal, each of the input signal and the output signal being at a logic level that is either a first logic level or a second logic level, the logic level of the input signal being based on a magnitude relationship between a temperature of the switching device and a predetermined temperature; and a driver circuit configured to switch the switching device, in response to a drive signal for driving the switching device and the output signal, the signal output circuit including a first capacitor, a charge-discharge circuit configured to in a case where the output signal is at the first logic level, charge the first capacitor when the input signal is at the second logic level, and discharge the first capacitor when the output signal reaches the second logic level, and in a case where the output signal is at the second logic level, charge the first capacitor when the input signal is at the first logic level, and discharge the first capacitor when the output signal reaches the first logic level, and an inverting circuit configured to invert the logic level of the output signal, in response to a charge voltage of the first capacitor exceeding a reference voltage.

### BRIEF DESCRIPTION OF THE DRAWINGS

FIG. 1 is a diagram illustrating an example of a semiconductor module 10.

FIG. 2 is a diagram illustrating a configuration example of a signal output circuit 52a.

FIG. 3 is a diagram illustrating an operation example of a signal output circuit 52a.

FIG. 4 is a diagram illustrating a configuration example of a signal output circuit 52b.

FIG. 5 is a diagram illustrating an operation example of a signal output circuit 52b.

FIG. 6 is a diagram illustrating a configuration example of a signal output circuit 52c.

FIG. 7 is a diagram illustrating an operation example of a signal output circuit 52c.

FIG. 8 is a diagram illustrating a configuration example of a signal output circuit 52d.

### DETAILED DESCRIPTION

At least following matters will become apparent from the descriptions of the present description and the accompanying drawings. The same or equivalent constituent elements, members, and the like illustrated in the drawings are given the same reference numerals, and repetitive description is omitted as appropriate.

### Embodiments

### Overview of Semiconductor Module 10

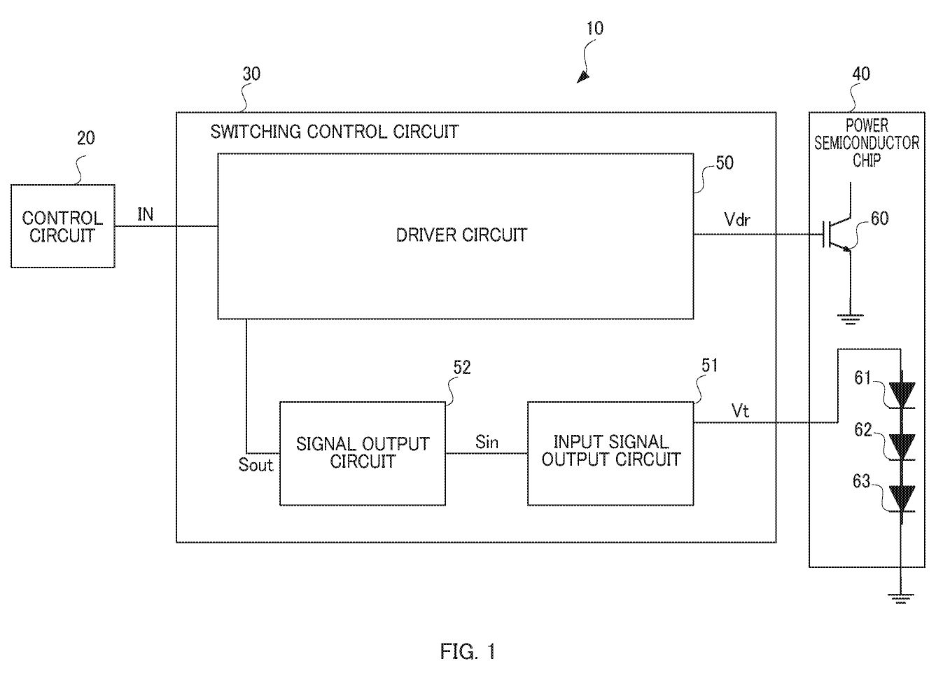

FIG. 1 is a diagram illustrating a configuration example of a semiconductor module 10 according to an embodiment of the present disclosure.

The semiconductor module 10 of an embodiment of the present disclosure is a semiconductor device that drives a power semiconductor chip 40 in response to a drive signal IN from a control circuit 20. The semiconductor module 10 includes a switching control circuit 30 and the power semiconductor chip 40.

The switching control circuit 30 drives the power semiconductor chip 40 in response to the drive signal IN from the control circuit 20. The switching control circuit 30 includes a driver circuit 50, an input signal output circuit 51, and a signal output circuit 52.

The driver circuit 50 outputs a drive voltage Vdr to switch the power semiconductor chip 40 (i.e., Insulated Gate Bipolar Transistor (IGBT) 60 (described below)) in response to the drive signal IN and a signal Sout (described below).

The input signal output circuit 51 outputs a signal Sin of a logic level that is based on the magnitude relationship between the temperature of the power semiconductor chip 40 and a predetermined temperature. In specific, the input signal output circuit 51 compares a voltage Vt corresponding to the temperature of the power semiconductor chip 40 with a reference voltage (not illustrated), to thereby output a signal Sin.

The signal output circuit 52 outputs the output signal Sout corresponding to the input signal Sin. The signal output circuit 52 will be described in detail below.

The power semiconductor chip 40 includes the IGBT 60 and diodes 61 to 63. The IGBT 60 is switched based on the drive voltage Vdr from the switching control circuit 30. Note that the IGBT 60 corresponds to a "switching device".

The diodes 61 to 63 are temperature detection elements provided in the vicinity of the IGBT 60, to detect the temperature corresponding to the heat generated at the IGBT 60. Note that a current of a predetermined current value flows through the diode 61 to 63 from the input signal output circuit 51, and the diode 61 to 63 output the voltage Vt to the input signal output circuit 51 as a forward voltage.

### Configuration of signal output circuit 52a

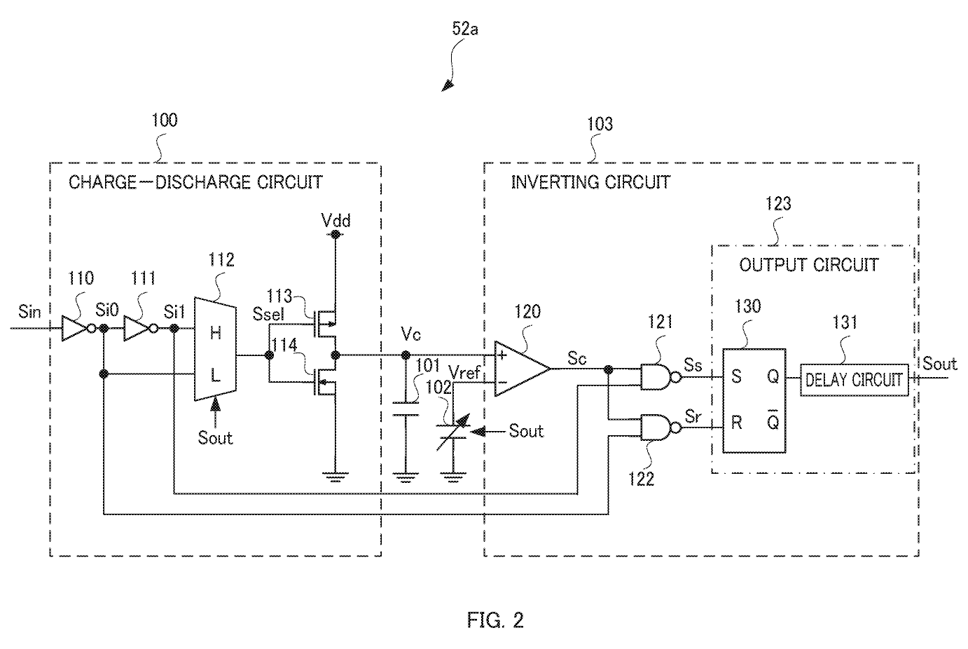

FIG. 2 is a diagram illustrating a configuration example of a signal output circuit 52a. In response to receiving of the signal Sin at a high level (hereinafter, referred to as high or high level) during a detection period tdH, the signal output circuit 52a outputs the high signal Sout. On the other hand, in response to receiving of the signal Sin at a low level (hereinafter referred to as low or low level) during a detection period tdL, the signal output circuit 52a outputs the low signal Sout.

The signal output circuit 52a includes a charge-discharge circuit 100, a capacitor 101, a reference voltage output circuit 102, and an inverting circuit 103.

The charge-discharge circuit 100 charges and discharges the capacitor 101 in response to the signal Sin. In specific, in the case where the signal Sout is low and when the signal Sin is high, the charge-discharge circuit 100 charges the capacitor 101. Meanwhile, in the case where the signal Sout is high and when the signal Sin is low, the charge-discharge circuit 100 charges the capacitor 101. The charge-discharge circuit 100 discharges the capacitor 101 in response to the logic level of the signal Sout being inverted. Note that in an embodiment of the present disclosure, the low level corresponds to a "first logic level" and the high level corresponds to a "second logic level".

The charge-discharge circuit 100 includes an inverter circuits 110, 111, a selector 112, a P-channel metal–oxide–semiconductor (PMOS) transistor 113, and an N-channel metal–oxide–semiconductor (NMOS) transistor 114.

The inverter circuit 110 outputs a low signal Si0 in response to the high signal Sin, and outputs a high signal Si0 in response to the low signal Sin.

The inverter circuit 111 outputs a low signal Si1 in response to the high signal Si0, and outputs a high signal Si1 in response to the low signal Si0.

The selector 112 outputs either the signal Si0 or the signal Si1, as a signal Ssel, in response to the signal Sout. In specific, the selector 112 outputs the signal Si0, as the signal Ssel, in response to the low signal Sout. On the other hand, the selector 112 outputs the signal Si1, as the signal Ssel, in response to the high signal Sout.

The PMOS transistor 113 and the NMOS transistor 114 constitute an inverter circuit, and charge the capacitor 101 in response to the low signal Ssel and discharges the capacitor 101 in response to the high signal Ssel. Note that the capacitor 101 corresponds to a "first capacitor".

The reference voltage output circuit 102 outputs the reference voltage VrefH to measure the detection period tdH or outputs the reference voltage VrefL (different from the reference voltage VrefH) to measure the detection period tdL, in response to the signal Sout. In specific, the reference voltage output circuit 102 outputs the reference voltage VrefH when the signal Sout is low, and outputs the reference voltage VrefL when the signal Sout is high. Note that the reference voltage output circuit 102 corresponds to a "reference voltage output circuit", the level of the reference voltage VrefH corresponds to the "first level", and the level of the reference voltage VrefL corresponds to the "second level".

The inverting circuit 103 inverts the logic level of the signal Sout, in response to the charge voltage Vc of the capacitor 101 exceeding the reference voltage VrefH or VrefL. In specific, when the signal Sout is low, the inverting circuit 103 outputs the high signal Sout in response to the charge voltage Vc exceeding the reference voltage VrefH. On the other hand, when the signal Sout is high, the inverting circuit 103 outputs the low signal Sout in response to the charge voltage Vc exceeding the reference voltage VrefL.

The inverting circuit 103 includes a comparator 120, a NAND circuits 121, 122, and an output circuit 123.

The comparator 120 compares the charge voltage Vc with the reference voltage VrefH or VrefL. In specific, the comparator 120 outputs the high signal Sc, when the signal Sout is low and the charge voltage Vc exceeds the reference voltage VrefH, or when the signal Sout is high and the charge voltage Vc exceeds the reference voltage VrefL.

On the other hand, the comparator 120 outputs the low signal Sc, when the signal Sout is low and the charge voltage Vc is lower than the reference voltage VrefH, or when the signal Sout is high and the charge voltage Vc is lower than the reference voltage VrefL. Note that the comparator 120 corresponds to a "comparator circuit", and the signal Sc corresponds to a "comparison result".

When the signal Sin is high and the charge voltage Vc exceeds the reference voltage VrefH, the NAND circuit 121 outputs a signal Ss. In specific, the NAND circuit 121 calculates a logical AND in response to the signals Sc and Si1, inverts a result thereof, and outputs an inverted result as the signal Ss. Note that the NAND circuit 121 corresponds to a "first output circuit" and the low signal Ss corresponds to a "first signal.

The NAND circuit 122 outputs a signal Sr when the signal Sin is low and the charge voltage Vc exceeds the reference voltage VrefL. In specific, the NAND circuit 122 calculates a logical AND in response to the signals Sc and the signal Si0, inverts a result thereof, and outputs an inverted result as the signal Sr. Note that the NAND circuit 122 corresponds to a "second output circuit" and the low signal Sr corresponds to a “second signal”.

The output circuit 123 outputs the signal Sout in response to the signals Ss and Sr. In specific, the output circuit 123 outputs the high signal Sout in response to the low signal Ss, and outputs the low signal Sout in response to the low signal Sr. Note that the output circuit 123 does not change the signal Sout even if receiving the high signals Ss and Sr. Note that the output circuit 123 corresponds to a "third output circuit".

The output circuit 123 includes an SR flip-flop 130 and a delay circuit 131.

The SR flip-flop 130 causes a Q output thereof to go high in response to the low signal Ss, and causes the Q output to go low in response to the low signal Sr. Note that the SR flip-flop 130 corresponds to a "first latch circuit" and the Q output corresponds to a "first latch signal”.

The delay circuit 131 delays the Q output of the SR flip-flop 130 by a predetermined time period td and outputs a result as the signal Sout. Although the signal output circuit 52a can operate without the delay circuit 131, the delay circuit 131 is provided to suppress unstable operation caused by manufacturing variations and the like. Further, the delay circuit 131 corresponds to a "first delay circuit".

### Operation of signal output circuit 52a

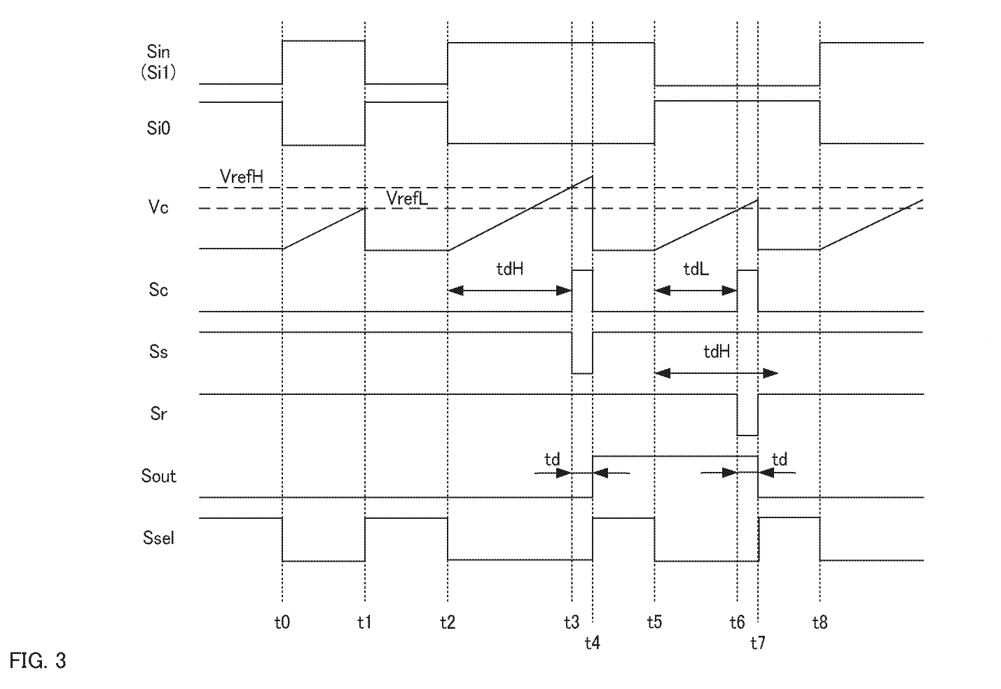

FIG. 3 is a diagram illustrating an operation example of the signal output circuit 52a. In FIG. 3, a description will be given assuming that the reference voltage VrefH is higher than the reference voltage VrefL. In this case, the detection period tdH is longer than the detection period tdL.

At time t0, at which the high signal Sin is inputted, the signal Sout is low, and thus the selector 112 outputs the low signal Ssel in response to the low signal Si0. Then, the PMOS transistor 113 is turned on, and thus the capacitor 101 starts to be charged.

At time t1, at which the low signal Sin is inputted, the signal Sout is low, and thus the selector 112 outputs the high signal Ssel in response to the high signal Si0. Then, the NMOS transistor 114 is turned on, and thus the capacitor 101 is discharged and the charge voltage Vc results in reaching a ground level. Since the charge voltage Vc does not exceed the reference voltage VrefH, the comparator 120 outputs the low signal Sc.

At time t2, at which the high signal Sin is inputted, the signal Sout is low, and thus the selector 112 outputs the low signal Ssel in response to the low signal Si0. Then, the PMOS transistor 113 is turned on, and thus the capacitor 101 starts to be charged.

At time t3, at which the charge voltage exceeds the reference voltage VrefH, the comparator 120 outputs the high signal Sc. The NAND circuit 121 then outputs the low signal Ss in response to the high signal Sc and the high signal Si1. Then, the SR flip-flop 130 causes the Q output thereof to go high. Note that the time period from time t2 to t3 corresponds to the detection period tdH.

At time t4, at which the predetermined time period td has elapsed since time t3, the delay circuit 131 outputs the high signal Sout. As such, in response to receiving of the high signal Sin continuously during the detection period tdH, the signal output circuit 52a outputs the high signal Sout. Since the signal Sout goes high, the selector 112 outputs the high signal Ssel in response to the high signal Si1. Then, the NMOS transistor 114 is turned on, and thus the capacitor 101 is discharged.

At time t5, at which the low signal Sin is inputted, the signal Sout is high, and thus the selector 112 outputs the low signal Ssel in response to the low signal Si1. Then, the PMOS transistor 113 is turned on, and thus the capacitor 101 is charged.

At time t6, at which the charge voltage Vc exceeds the reference voltage VrefL, the comparator 120 outputs the high signal Sc. Then, the NAND circuit 122 outputs the low signal Sr in response to the high signal Sc and the high signal Si0. Then, the SR flip-flop 130 causes the Q output thereof to go low. Note that the time period from time t5 to t6 corresponds to the detection period tdL.

At time t7, at which the predetermined time period td has elapsed since time t6, the delay circuit 131 outputs the low signal Sout. As such, in response to receiving of the low signal Sin continuously during the detection period tdL, the signal output circuit 52a outputs the low signal Sout. Since the signal Sout goes low, the selector 112 outputs the high signal Ssel in response to the high signal Si0. Then, the NMOS transistor 114 is turned on, and thus the capacitor 101 is discharged.

Upon receiving the high signal Sin at time t8, the signal output circuit 52a repeats the same operation. Note that in the case where the signal Sout is high and the low signal Sin is received for a time period shorter than the detection period tdL as well, the signal output circuit 52a does not output the low signal Sout, in other words, does not invert the logic level of the signal Sout, as in the time period from the time t0 to t1.

Further, in FIG. 3, a description has been given assuming that the reference voltage VrefH is higher than the reference voltage VrefL, however, the reference voltage VrefH may be lower than the reference voltage VrefL, in order to cause the detection period tdH to be shorter than the detection period tdL. This makes it possible to provide a signal output circuit with a small circuit scale while removing the noise of the input signal.

### Modifications

### Configuration of signal output circuit 52b

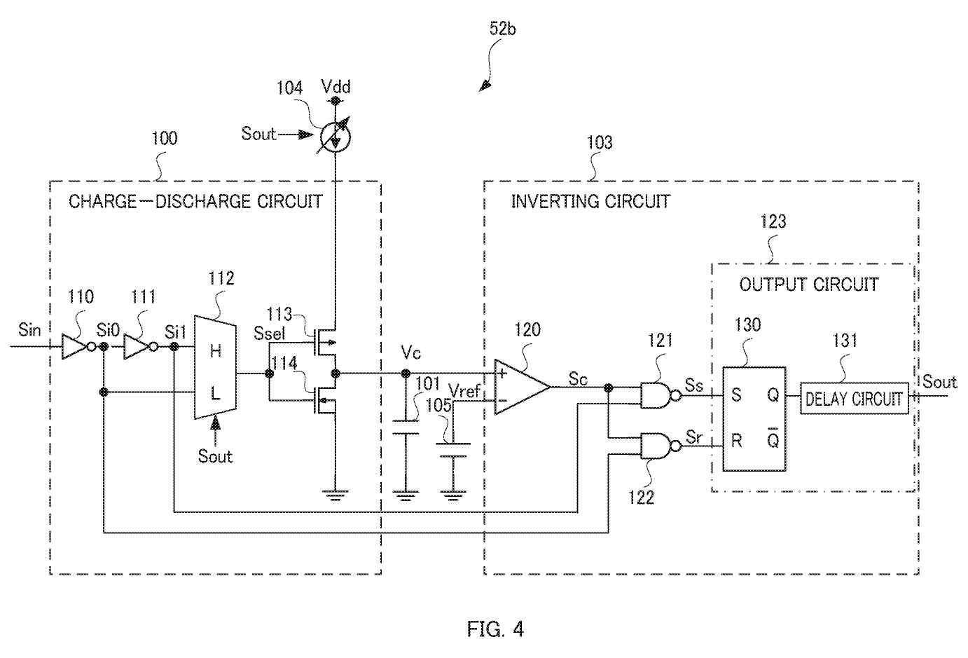

FIG. 4 is a diagram illustrating a configuration example of a signal output circuit 52b which is a modification of the signal output circuit 52a. The signal output circuit 52b, as with the signal output circuit 52a, outputs the high signal Sout in response to receiving of the high signal Sin during the detection period tdH. On the other hand, the signal output circuit 52b, as with the signal output circuit 52a, outputs the low signal Sout in response to receiving of the low signal Sin during the detection period tdL.

The signal output circuit 52b includes the charge-discharge circuit 100, the capacitor 101, the inverting circuit 103, a current source 104, and a reference voltage output circuit 105.

The current source 104 supplies a current corresponding to the signal Sout, to charge the capacitor 101, and is provided between the power supply voltage Vdd and the source electrode of the PMOS transistor 113. In specific, when the signal Sout is low, the current source 104 supplies the current of a current value I0, to thereby charge the capacitor 101, and when the signal Sout is high, the current source 104 supplies the current of a current value I1, which is greater than the current value I0, to thereby charge the capacitor 101. Note that the current value I0 corresponds to a "current value of a first value" and the current value I1 corresponds to a "current value of a second value".

The reference voltage output circuit 105 outputs a reference voltage Vref.

### Operation of signal output circuit 52b

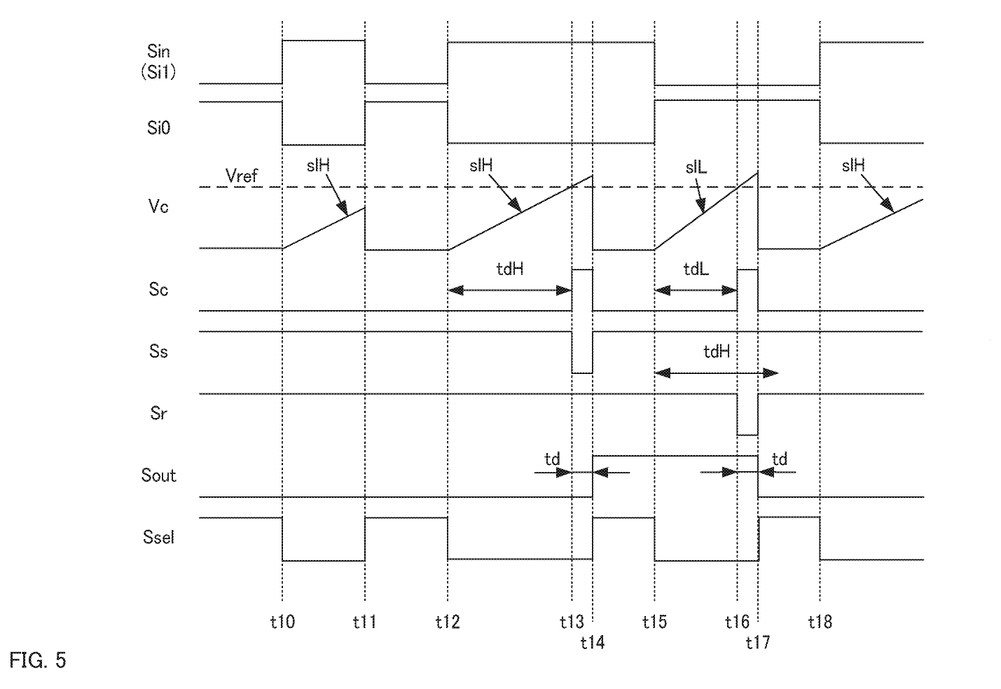

FIGS. 5 is diagram illustrating an operation example of the signal output circuit 52b.

At time t10, at which the high signal Sin is inputted, the signal Sout is low, and thus the selector 112 outputs the low signal Ssel in response to the low signal Si0. Then, the PMOS transistor 113 is turned on, and thus the capacitor 101 starts to be charged with the current of the current value 10. The slope of the charge voltage Vc in this event is defined as a slope slH based on the current of the current value I0.

At time t11, at which the low signal Sin is inputted, the signal Sout is low, and thus the selector 112 outputs the high signal Ssel in response to the high signal Si0. Then, the NMOS transistor 114 is turned on, and thus the capacitor 101 is discharged and the charge voltage Vc results in reaching the ground level. Since the charge voltage Vc does not exceed the reference voltage Vref, the comparator 120 outputs the low signal Sc.

At time t12, at which the high signal Sin is inputted, the signal Sout is low, and thus the selector 112 outputs the low signal Ssel in response to the low signal Si0. Then, the PMOS transistor 113 is turned on, and thus the capacitor 101 starts to be charged with the current of the current value 10. Further, the slope of the charge voltage Vc is the slope slH.

At time t13, at which the charge voltage Vc exceeds the reference voltage Vref, the comparator 120 outputs the high signal Sc. The NAND circuit 121 then outputs the low signal Ss in response to the high signal Sc and the high signal Si1. Then, the SR flip-flop 130 causes the Q output thereof to go high. The time period from time t12 to t13 corresponds to the detection period tdH.

At time t14, at which the predetermined time period td has elapsed since time t13, the delay circuit 131 outputs the high signal Sout. As such, in response to receiving of the high signal Sin continuously during the detection period tdH, the signal output circuit 52b outputs the high signal Sout. Since the signal Sout goes high, the selector 112 outputs the high signal Ssel in response to the high signal Si1. Then, the NMOS transistor 114 is turned on, and thus the capacitor 101 is discharged.

At time t15, at which the low signal Sin is inputted, the signal Sout is high, and thus the selector 112 outputs the low signal Ssel in response to the low signal Si1. Then, the PMOS transistor 113 is turned on, and thus the capacitor 101 is charged with the current of the current value I1. The slope of the charge voltage Vc in this event is defined as a slope slL based on the current of the current value I1. The slope slL is greater than the slope slH.

At time t16, at which the charge voltage Vc exceeds the voltage Vref, the comparator 120 outputs the high signal Sc. The NAND circuit 122 then outputs the low signal Sr in response to the high signal Sc and the high signal Si0. Then, the SR flip-flop 130 causes the Q output thereof to go low. The time period from time t15 to t16 corresponds to the detection period tdL.

At time t17, at which the predetermined time period td has elapsed since time t16, the delay circuit 131 outputs the low signal Sout. As such, in response to receiving of the low signal Sin continuously during the detection period tdL, the signal output circuit 52b outputs the low signal Sout. Since the signal Sout goes low, the selector 112 outputs the high signal Ssel in response to the high signal Si0. Then, the NMOS transistor 114 is turned on, and thus the capacitor 101 is discharged.

Upon receiving the high signal Sin at time t18, the signal output circuit 52b repeats the same operation. Note that in the case where the signal Sout is high and the low signal Sin is received for a time period shorter than the detection period tdL as well, the signal output circuit 52b does not output the low signal Sout, in other words, does not invert the logic level of the signal Sout, as in the time period from time t10 to t11.

Further, in FIG. 5, a description has been given assuming that the current value I0 is smaller than the current value I1, however, the current value I0 may be larger than the current value I1, in order to cause the detection period tdH to be shorter than the detection period tdL. This makes it possible to provide a signal output circuit with a small circuit scale while removing the noise of the input signal.

### Configuration of signal output circuit 52c

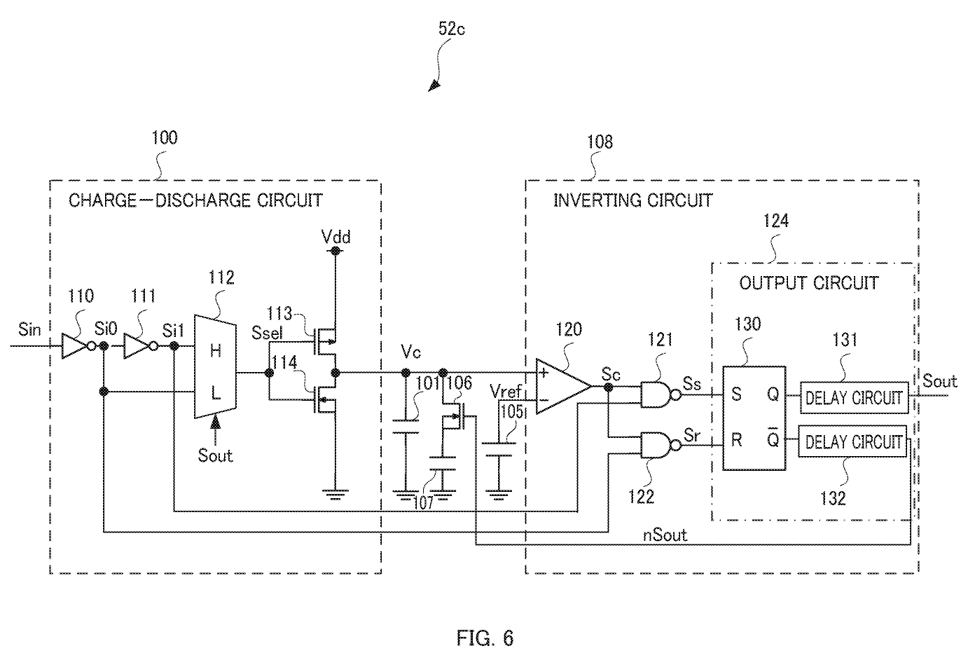

FIG. 6 is a diagram illustrating a configuration example of a signal output circuit 52c, which is a modification of the signal output circuit 52a. The signal output circuit 52c, as with the signal output circuit 52a, outputs the high signal Sout in response to receiving of the high signal Sin during the detection period tdH. On the other hand, the signal output circuit 52c, as with the signal output circuit 52a, outputs the low signal Sout in response to receiving of the low signal Sin during the detection period tdL.

The signal output circuit 52c includes the charge-discharge circuit 100, the capacitor 101, a capacitor 107, an NMOS transistor 106, and an inverting circuit 108.

The NMOS transistor 106 and the capacitor 107 are connected in series, and are connected in parallel with the capacitor 101. The capacitor 107 is located between the NMOS transistor 106 and the ground. Then, the NMOS transistor 106 is turned on in response to the low signal Sout or the high signal nSout, and is turned off in response to the high signal Sout or the low signal nSout. Further, upon turning on of the NMOS transistor 106, the capacitor 107 is charged and discharged together with the capacitor 101.

Accordingly, between the ground and the connection point between the PMOS transistor 113 and the NMOS transistor 114, the capacitor having a capacitance value C0 or C1 is connected based on on/off of the NMOS transistor 106. Note that the capacitance value when the capacitors 101, 107 are charged is referred to as the capacitance value C1, and the capacitance value when only the capacitor 101 is charged is referred to as the capacitance value C0. Further, the NMOS transistor 106 corresponds to a "switch", and the capacitor 107 corresponds to a "second capacitor".

The inverting circuit 108, as with the inverting circuit 103, inverts the logic level of the signal Sout in response to the charge voltage Vc exceeding the reference voltage Vref. In specific, when the signal Sout is low, the inverting circuit 108 outputs the high signal Sout in response to the charge voltage Vc exceeding the reference voltage Vref. On the other hand, when the signal Sout is high, the inverting circuit 108 outputs the low signal Sout in response to the charge voltage Vc exceeding the reference voltage Vref.

The inverting circuit 108 includes the comparator 120, the NAND circuits 121, 122, and an output circuit 124.

The output circuit 124 outputs the signals Sout and nSout in response to the signals Ss and Sr. In specific, the output circuit 124 outputs the high signal Sout and the low signal nSout in response to the low signal Ss, and outputs the low signal Sout and the high signal nSout in response to the low signal Sr. Note that the output circuit 124 does not change the signals Sout and nSout even when receiving the high signals Ss and Sr.

The output circuit 124 includes the SR flip-flop 130 and the delay circuit 131 and a delay circuit 132. Note that the SR flip-flop 130 corresponds to a "second latch circuit".

The delay circuit 132 delays the Q-bar output of the SR flip-flop 130 by the predetermined time period td and outputs a resultant signal as the signal nSout. Note that the signal output circuit 52c can operate without the delay circuit 132, as with the delay circuit 131, but the delay circuit 132 is provided because the delay circuit 131 is provided. Further, the delay circuit 132 corresponds to a "second delay circuit", the Q-bar output of the SR flip-flop 130 corresponds to a "second latch signal", and the signal nSout corresponds to a "control signal".

### Operation of signal output circuit 52c

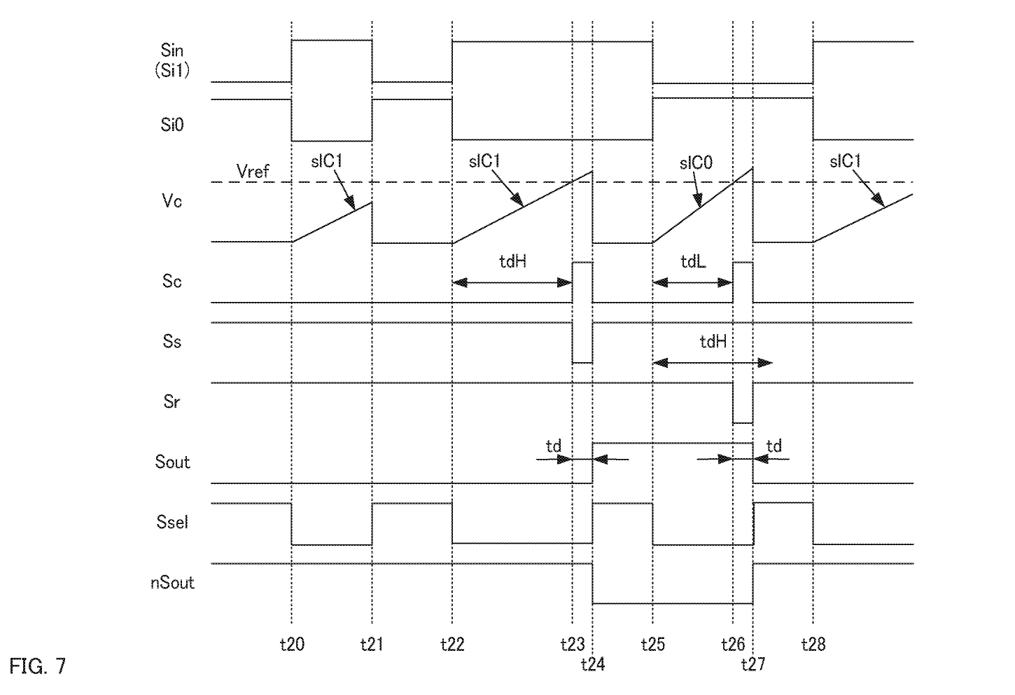

FIG. 7 is a diagram illustrating an operation example of a signal output circuit 52c.

At time t20, at which the high signal Sin is inputted, the signal Sout is low, and thus the selector 112 outputs the low signal Ssel in response to the low signal Si0. Then, the PMOS transistor 113 is turned on, and thus the capacitors 101, 107 start to be charged. In this event, the slope of the charge voltage Vc is defined as a slope slC1 that is based on the capacitance value C1.

At time t21, at which the low signal Sin is inputted, the signal Sout is low, and thus the selector 112 outputs the high signal Ssel in response to the high signal Si0. Then, the NMOS transistor 114 is turned on, and thus the capacitors 101, 107 are discharged and the charge voltage Vc results in reaching the ground level. Since the charge voltage Vc does not exceed the reference voltage Vref, the comparator 120 outputs the low signal Sc.

At time t22, at which the high signal Sin is inputted, the signal Sout is low, and thus the selector 112 outputs the low signal Ssel in response to the low signal Si0. Then, the PMOS transistor 113 is turned on, and thus the capacitors 101, 107 start to be charged. The slope of the charge voltage Vc is the slope slC1.

At time t23, at which the charge voltage Vc exceeds the reference voltage Vref, the comparator 120 outputs the high signal Sc. The NAND circuit 121 then outputs the low signal Ss in response to the high signal Sc and the high signal Si1. Then, the SR flip-flop 130 causes the Q output thereof to go high and the Q-bar output thereof to go low. Note that the time period from time t22 to t23 corresponds to the detection period tdH.

At time t24, at which the predetermined time period td has elapsed since time t23, the delay circuit 131 outputs the high signal Sout, and the delay circuit 132 outputs the low signal nSout. As such, in response to receiving of the high signal Sin continuously during the detection period tdH, the signal output circuit 52c outputs the high signal Sout. Since the signal Sout goes high, the selector 112 outputs the high signal Ssel in response to the high signal Si1. Then, the NMOS transistor 114 is turned on, and thus the capacitors 101,107 are discharged.

At time t25, at which the low signal Sin is inputted, the signal Sout is high, and thus the selector 112 outputs the low signal Ssel in response to the low signal Si1. Then, the PMOS transistor 113 is turned on, and thus the capacitor 101 is charged. Note that the slope of the charge voltage Vc in this event is defined as a slope slC0 that is based on the capacitance value C0. The slope slC0 is greater than the slope slC1.

At time t26, at which the charge voltage Vc exceeds the reference voltage Vref, the comparator 120 outputs the high signal Sc. Then, the NAND circuit 122 outputs the low signal Sr in response to the high signal Sc and the high signal Si0. Then, the SR flip-flop 130 causes the Q output thereof to go low and the Q-bar output thereof to go high. Note that the time period from time t25 to t26 corresponds to the detection period tdL.

At time t27, at which the predetermined time period td has elapsed since time t26, the delay circuit 131 outputs the low signal Sout, and the delay circuit 132 outputs the high signal nSout. As such, in response to receiving of the low signal Sin continuously during the detection period tdL, the signal output circuit 52c outputs the low signal Sout. Since the signal Sout goes low, the selector 112 outputs the high signal Ssel, based on the high signal Si0. Then, the NMOS transistor 114 is turned on, and thus the capacitor 101 is discharged.

At time t28, at which the high signal Sin is inputted, the signal output circuit 52c repeats the same operation. Note that in the case where the signal Sout is high and the low signal Sin is received for a time period shorter than the detection period tdL as well, the signal output circuit 52c does not output the low signal Sout, in other words, does not invert the logic level of the signal Sout, as in the time period from time t20 to t21.

Further, in FIG. 7, the capacitors 101, 107 are charged to wait for the detection period tdH, and the capacitor 101 is charged to wait for the detection period tdL, but by controlling the NMOS transistor 106 with the signal Sout, the detection period tdH can be made shorter than the detection period tdL. This makes it possible to provide a signal output circuit with a small circuit scale while removing the noise of the input signal.

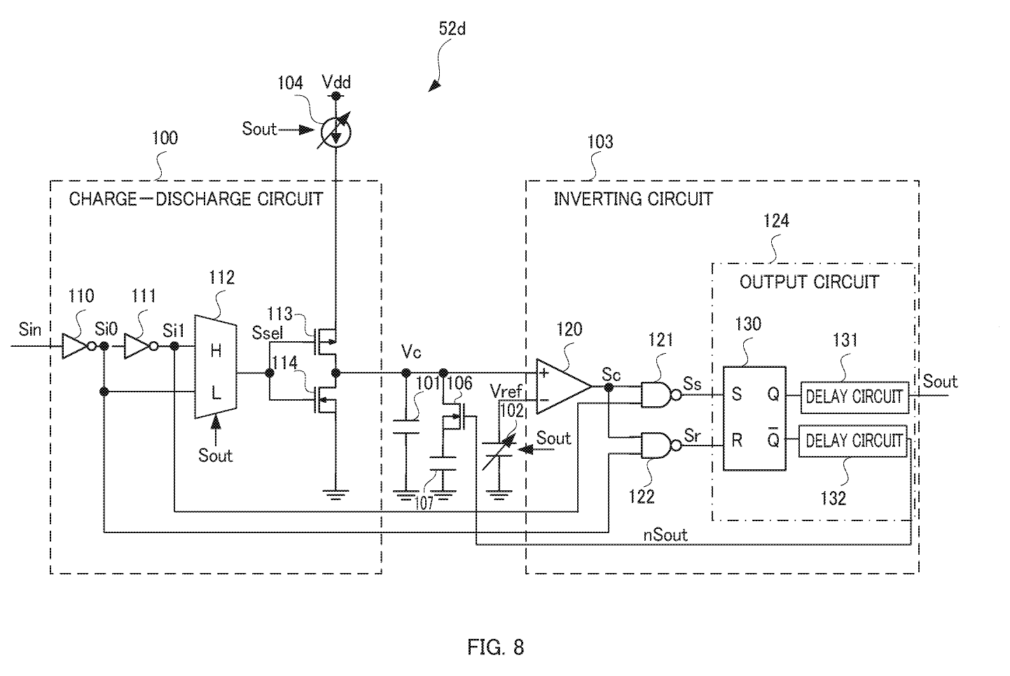

FIG. 8 is a diagram illustrating a configuration example of a signal output circuit 52d. With the reference voltage being set to either the reference voltage VrefH or VrefL, the signal output circuit 52a waits for the corresponding detection period tdH or tdL. Further, with the current value of the current from the current source 104 being set to either the current value I0 or I1, the signal output circuit 52b waits for the corresponding detection period tdH or tdL. Furthermore, the signal output circuit 52c waits for the detection period tdH, tdL depending on whether the capacitor 107 is used in addition to the capacitor 101.

However, to implement the detection periods tdH, tdL, all of the reference voltage output circuit 102, the current source 104, and the NMOS transistor 106 and the capacitor 107 may be used as shown in FIG. 8. Further, to implement the detection periods tdH, tdL, at least two may be used among the reference voltage output circuit 102, the current source 104, and the NMOS transistor 106 and the capacitor 107.

In addition, in FIG. 1, the input signal output circuit 51 and the signal output circuit 52 are illustrated separately, however, the signal output circuit 52 may include the input signal output circuit 51.

### Summary

Hereinabove, the semiconductor module 10 according to an embodiment of the present disclosure has been described. The signal output circuit 52a includes the capacitor 101, the charge-discharge circuit 100, and the inverting circuit 103. This makes it possible to provide a signal output circuit with a small circuit scale while removing the noise of the input signal.

The inverting circuit 103 includes the comparator 120, the NAND circuits 121, 122, and the output circuit 123. This makes it possible to provide a signal output circuit with a small circuit scale, since only one single comparator is used to implement the detection periods tdH, tdL.

The output circuit 123 includes the SR flip-flop 130 and the delay circuit 131. Further, the signal output circuit 52a can operate even without the delay circuit 131, but the delay circuit 131 contributes to a stable operation, in view of manufacturing variations and the like. This makes it possible to perform a stable operation in view of manufacturing variations and the like.

The signal output circuit 52c includes the NMOS transistor 106 and the capacitor 107. Thus, the detection periods tdH, tdL can be implemented by varying the capacitance value in response to the signal Sout.

The output circuit 124 includes the SR flip-flop 130 and the delay circuit 132. Further, as with the delay circuit 131, the delay circuit 132 contributes to the stability of the operation. This makes it possible to stably operate considering manufacturing variations and the like.

The signal output circuit 52a includes the reference voltage output circuit 102. Thus, the detection periods tdH, tdL can be implemented by varying the voltage level of the reference voltage.

The signal output circuit 52b includes the current source 104. Thus, the detection periods tdH, tdL can be implemented by varying the current value of the current for charging the capacitor 101.

The signal output circuit 52a includes the input signal output circuit 51. Thus, even if noise is superimposed on the voltage Vt outputted from the diodes 61 to 63, the signal output circuit 52a can output the output signal Sout without including noise.

The signal output circuit 52 is suitable for use in the semiconductor module 10.

The present disclosure is directed to provision of a signal output circuit with a small circuit scale while removing the noise of an input signal.

According to the present disclosure, it is possible to provide a signal output circuit with a small circuit scale while removing the noise of an input signal.

Embodiment(s) of the present disclosure described above is/are simply to facilitate understanding of the present disclosure and is/are not in any way to be construed as limiting the present disclosure. The present disclosure may variously be changed or altered without departing from its essential features and encompass equivalents thereof.

What is claimed is:

1. A signal output circuit configured to output an output signal corresponding to an input signal thereof, each of the input signal and the output signal being at a logic level that is either a first logic level or a second logic level, the signal output circuit comprising:
a first capacitor;
a charge-discharge circuit configured to,
in a case where the output signal is at the first logic level, charge the first capacitor when the input signal is at the second logic level, and discharge the first capacitor when the output signal reaches the second logic level, and
in a case where the output signal is at the second logic level, charge the first capacitor when the input signal is at the first logic level, and discharges the first capacitor when the output signal reaches the first logic level; and
an inverting circuit configured to invert the logic level of the output signal, in response to a charge voltage of the first capacitor exceeding a reference voltage.

2. The signal output circuit according to claim 1, wherein the inverting circuit includes
a comparator circuit configured to compare the charge voltage with the reference voltage,
a first output circuit configured to output a first signal, in response to the comparator circuit outputting a comparison result indicating that the charge voltage exceeds the reference voltage, when the input signal is at the second logic level,
a second output circuit configured to output a second signal, in response to the comparator circuit outputting the comparison result, when the input signal is at the first logic level, and
a third output circuit configured to
output the output signal at the second logic level in response to the first signal, and
output the output signal at the first logic level in response to the second signal.

3. The signal output circuit according to claim 2, wherein the third output circuit includes
a first latch circuit configured to
output a first latch signal at the second logic level in response to the first signal, and
output the first latch signal at the first logic level in response to the second signal, and
a first delay circuit configured to delay the first latch signal by a predetermined time period, and output a resultant signal as the output signal.

4. The signal output circuit according to claim 2, further comprising:
a switch; and
a second capacitor located between the switch and a ground, wherein
the switch and the second capacitor are connected in parallel with the first capacitor, and
the third output circuit
turns on the switch, when the output signal is at the first logic level, and
turns off the switch, when the output signal is at the second logic level, and
the charge-discharge circuit charges and discharges the second capacitor together with the first capacitor, when the output signal is at the first logic level.

5. The signal output circuit according to claim 4, wherein the third output circuit includes
a second latch circuit configured to
output a second latch signal at the first logic level in response to the first signal, and
output the second latch signal at the second logic level in response to the second signal, and
a second delay circuit configured to
delay the second latch signal by a predetermined time period, and
output a resultant signal as a control signal, wherein
the switch is turned on, when the control signal is at the second logic level, and is turned off when the control signal is at the first logic level.

6. The signal output circuit according to claim 1, further comprising:
a reference voltage output circuit configured to
output the reference voltage of a first level, when the output signal is at the first logic level, and
output the reference voltage of a second level different from the first level, when the output signal is at the second logic level.

7. The signal output circuit according to claim 1, further comprising:
a current source configured to supply a current, which
has a first current value when the output signal is at the first logic level, and
has a second current value different from the first current value, when the output signal is at the second logic level, wherein
at least the first capacitor is charged with the current.

8. The signal output circuit according to claim 1, further comprising:
an input signal output circuit configured to output the input signal, of which the logic level is based on a magnitude relationship between a temperature of a switching device and a predetermined temperature.

9. A switching control circuit, comprising:
an input signal output circuit configured to output an input signal at a logic level that is based on a magnitude relationship between a temperature of a switching device and a predetermined temperature;
a signal output circuit configured to output an output signal corresponding to the input signal; and
a driver circuit configured to switch the switching device, in response to a drive signal for driving the switching device and the output signal.

10. A semiconductor device, comprising:
a switching device;
a temperature detection element configured to detect a temperature of the switching device;
an input signal output circuit configured to output an input signal;
a signal output circuit configured to output an output signal corresponding to the input signal, each of the input signal and the output signal being at a logic level that is either a first logic level or a second logic level, the logic level of the input signal being based on a magnitude relationship between a temperature of the switching device and a predetermined temperature; and
a driver circuit configured to switch the switching device, in response to a drive signal for driving the switching device and the output signal,
the signal output circuit including
a first capacitor,
a charge-discharge circuit configured to
in a case where the output signal is at the first logic level, charge the first capacitor when the input signal is at the second logic level, and discharge the first capacitor when the output signal reaches the second logic level, and
in a case where the output signal is at the second logic level, charge the first capacitor when the input signal is at the first logic level, and discharge the first capacitor when the output signal reaches the first logic level, and
an inverting circuit configured to invert the logic level of the output signal, in response to a charge voltage of the first capacitor exceeding a reference voltage.
